(19) United States
(12) Patent Application Publication
(10) Pub. No.: US 2019/0318912 A1
(43) Pub. Date: Oct. 17, 2019

(54) PLASMA PROCESSING APPARATUS

(71) Applicant: TOKYO ELECTRON LIMITED, Tokyo (JP)

(72) Inventors: Naoyuki UMEHARA, Miyagi (JP); Masaki NISHIKAWA, Miyagi (JP)

(73) Assignee: TOKYO ELECTRON LIMITED, Tokyo (JP)

(21) Appl. No.: 16/382,637

(22) Filed: Apr. 12, 2019

(30) Foreign Application Priority Data
Apr. 12, 2018 (JP) 2018-077054

(51) Int. Cl. H01J 37/32; H01L 21/67

(52) U.S. Cl. CPC H01J 37/32165; H01L 21/67069; H01J 37/32183; H01J 2237/334; H01J 2237/002; H01J 2237/24564; H01J 37/32715

(57) ABSTRACT

A plasma processing apparatus includes a radio-frequency power supply that outputs modulated radio-frequency power which is generated such that a power level during a first period is higher than a power level during a second period that alternates with the first period. The plasma processing apparatus also includes a matching device that sets a load side impedance of the radio-frequency power supply during a monitoring period within the first period to an impedance that differs from an output impedance of the radio-frequency power supply. The monitoring period starts after a predetermined time length elapses from a start point of the first period. The radio-frequency power supply adjusts the power level of the modulated radio-frequency power such that a load power level, which is a difference between a power level of a traveling wave and a power level of a reflected wave, becomes a designated power level.

### CROSS-REFERENCE TO RELATED APPLICATIONS

This application is based on and claims priority from Japanese Patent Application No. 2018-077054, filed on Apr. 12, 2018 with the Japan Patent Office, the disclosure of which is incorporated herein in its entirety by reference.

### TECHNICAL FIELD

Embodiments of the present disclosure relate to a plasma processing apparatus.

### BACKGROUND

In the manufacture of electronic devices, a plasma processing apparatus is used. The plasma processing apparatus includes a chamber, electrodes, a radio-frequency power supply, and a matching device. In order to excite the gas within the chamber to generate plasma, high-frequency power is given from the radio-frequency power supply to the electrode. The matching device is configured to match the impedance on the load side of the radio-frequency power supply to the output impedance of the radio-frequency power supply.

Regarding the plasma processing apparatus, there has been proposed a method of using radio-frequency power (hereinafter, “modulated radio-frequency power”) which is modulated such that a power level thereof is alternately increased and decreased. In more detail, the modulated radio-frequency power is generated such that a power level thereof during a first period is higher than a power level thereof during a second period that alternates with the first period. Japanese Patent Laid-open Publication No. 2013-125892 discloses the use of the modulated radio-frequency power.

In the case of using the modulated radio-frequency power, the matching device operates to match the load side impedance, which is measured during a monitoring period in the first period, with the output impedance (e.g., a matching point of 50+j0 [Ω]) of the radio-frequency power supply. The monitoring period is a period that starts after a predetermined time length elapses from a start point of the first period. Since the reflected wave power is relatively high immediately after the start of the first period, the monitoring period is set in the way described above.

### SUMMARY

In an aspect, a plasma processing apparatus is provided. The plasma processing apparatus includes a chamber, a radio-frequency power supply, an electrode, and a matching device. The electrode is electrically connected to the radio-frequency power supply in order to generate plasma in the chamber. The matching device is connected between the radio-frequency power supply and the electrode. The radio-frequency power supply is configured to output radio-frequency power (hereinafter, referred to as “modulated radio-frequency power”) which is generated such that a power level during a first period is higher than a power level during a second period alternating with the first period. The matching device sets a load side impedance of the radio-frequency power supply during a monitoring period within the first period to an impedance that differs from an output impedance of the radio-frequency power supply. The monitoring period is a period starting after a predetermined time length elapses from a start point the first period. The radio-frequency power supply adjusts the power level of the radio-frequency power such that a load power level, which is a difference between a power level of a traveling wave and a power level of a reflected wave, becomes a designated power level.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF DRAWINGS

FIG. 1 is a view schematically illustrating a plasma processing apparatus according to an embodiment.

FIG. 2 is a view illustrating an exemplary timing chart of a first mode.

FIG. 3 is a view illustrating an exemplary timing chart of a second mode.

FIG. 4 is a view illustrating an exemplary timing chart of a third mode.

FIG. 5 is a view illustrating exemplary configurations of a radio-frequency power supply 36 and a matching device 40 of the plasma processing apparatus 1 illustrated in FIG. 1.

FIG. 6 is a view illustrating an exemplary configuration of a sensor of the matching device 40 of the plasma processing apparatus 1 illustrated in FIG. 1.

FIG. 7 is a view illustrating exemplary configurations of a radio-frequency power supply 38 and a matching device 42 of the plasma processing apparatus 1 illustrated in FIG. 1.

FIG. 8 is a view illustrating an exemplary configuration of a sensor of the radio-frequency power supply 38 of the plasma processing apparatus 1 illustrated in FIG. 1.

FIG. 9A is a view for explaining values measured in an experiment, and FIG. 9B is a graph showing an experimental result.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In an aspect, a plasma processing apparatus is provided. The plasma processing apparatus includes a chamber, a radio-frequency power supply, an electrode, and a matching device. The electrode is electrically connected to the radio-frequency power supply in order to generate plasma in the chamber. The matching device is connected between the radio-frequency power supply and the electrode. The radio-frequency power supply outputs radio-frequency power (hereinafter, referred to as “modulated radio-frequency power”) generated such that a power level during a first period is higher than a power level during a second period alternating with the first period. The matching device sets a load side impedance of the radio-frequency power supply during a monitoring period within the first period to an impedance that differs from an output impedance of the radio-frequency power supply. The monitoring period is a period starting after a predetermined time length elapses from a start point of the first period. The radio-frequency power supply adjusts the power level of the radio-frequency power such that a load power level, which is a difference between a power level of a traveling wave and a power level of a reflected wave, becomes a designated power level.

In an aspect, in a case where the modulated radio-frequency power is used in the plasma processing apparatus, the load side impedance during the monitoring period is set to an impedance that differs from an output impedance (matching point) of the radio-frequency power supply. As a result, reflection of the modulated radio-frequency power is reduced. In a case where the load side impedance differs from the matching point, the power level of the radio-frequency power is adjusted such that the load power level is a designated power level even though the reflection cannot be completely eliminated, and as a result, the modulated radio-frequency power having the designated power level is coupled to plasma.

In an embodiment, the matching device sets the load side impedance such that an absolute value of a reflection coefficient of the radio-frequency power is a designated value. In the embodiment, the designated value ranges from 0.3 to 0.5.

Hereinafter, various embodiments will be described in detail with reference to the drawings. Further, in the respective drawings, identical or equivalent constituent elements are denoted by the same reference numerals.

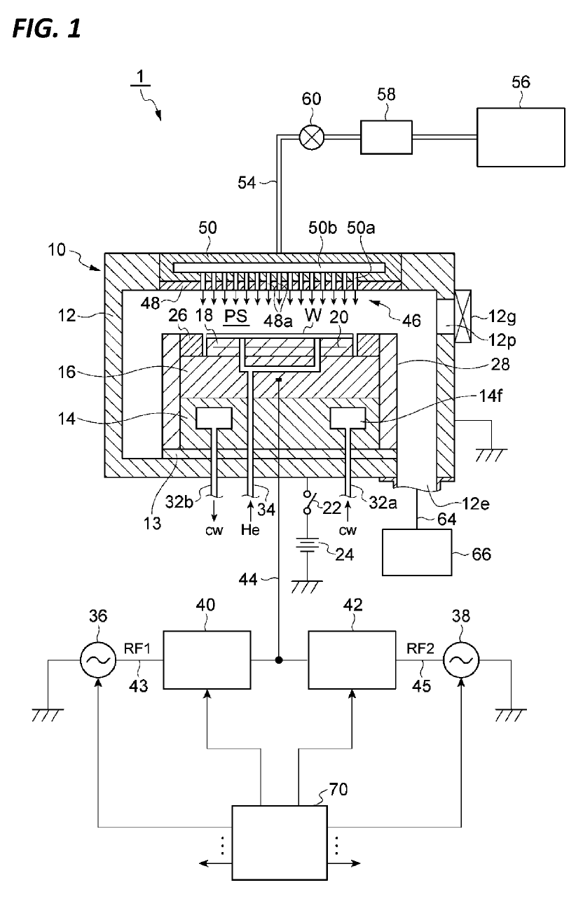

FIG. 1 is a view schematically illustrating a plasma processing apparatus according to an embodiment. The plasma processing apparatus 1 illustrated in FIG. 1 is a capacitively coupled plasma processing apparatus. The plasma processing apparatus 1 has a chamber 10. The chamber 10 provides an inner space.

The chamber 10 includes a chamber body 12. The chamber body 12 has an approximately cylindrical shape. The inner space of the chamber 10 is provided inside the chamber body 12. The chamber body 12 is made of a material such as, for example, aluminum. The inner wall surface of the chamber body 12 is anodized. The chamber body 12 is grounded. An opening 12p is formed in a side wall of the chamber body 12. A substrate W passes through the opening 12p when the substrate W is transported between the inner space of the chamber 10 and the outside of the chamber 10. The opening 12p is openable/closable by a gate valve 12g. The gate valve 12g is provided along the side wall of the chamber body 12.

An insulating plate 13 is provided on a bottom portion of the chamber body 12. The insulating plate 13 is made of, for example, ceramic. A support base 14 is provided on the insulating plate 13. The support base 14 has a substantially cylindrical shape. A susceptor 16 is provided on the support base 14. The susceptor 16 is made of a conductive material such as, for example, aluminum. The susceptor 16 constitutes a lower electrode. The susceptor 16 may be electrically connected to a radio-frequency power supply to be described later in order to generate plasma in the chamber 10.

An electrostatic chuck 18 is provided on the susceptor 16. The electrostatic chuck 18 is configured to hold a substrate W placed thereon. The electrostatic chuck 18 has a main body and an electrode 20. The main body of the electrostatic chuck 18 is formed of an insulator and has an approximately disc shape. The electrode 20 is a conductive film and is provided in the main body of the electrostatic chuck 18. A DC power supply 24 is electrically connected to the electrode 20 through a switch 22. When a DC voltage is applied from the DC power supply 24 to the electrode 20, an electrostatic attractive force is generated between the substrate W and the electrostatic chuck 18. The substrate W is attracted to the electrostatic chuck 18 by the generated electrostatic attractive force and held by the electrostatic chuck 18.

A focus ring 26 is arranged around the electrostatic chuck 18 and on the susceptor 16. The focus ring 26 is disposed so as to surround the edge of the substrate W. A cylindrical inner wall member 28 is attached on outer peripheral surfaces of the susceptor 16 and the support base 14. The inner wall member 28 is made of, for example, quartz.

A flow path 14f is formed inside the support base 14. The flow path 14f extends, for example, in a spiral shape with respect to a central axis that extends in the vertical direction. A heat exchange medium cw (e.g., a coolant such as a cooling water) is supplied to the flow path 14f from a supply device (e.g., a chiller unit) provided outside the chamber 10 via a pipe 32a. The heat exchange medium supplied to the flow path 14f is collected in the supply device via a pipe 32b. By adjusting the temperature of the heat exchange medium by the supply device, the temperature of the substrate W is adjusted. In addition, the plasma processing apparatus 1 has a gas supply line 34. The gas supply line 34 is provided to supply a heat transfer gas (e.g., He gas) to a portion between the upper surface of the electrostatic chuck 18 and the rear surface of the substrate W.

A conductor 44 (e.g., power supply rod) is connected to the susceptor 16. A radio-frequency power supply 36 is connected to the conductor 44 via a matching device 40. A radio-frequency power supply 38 is connected to the conductor 44 via a matching device 42. That is, the radio-frequency power supply 36 is connected to the lower electrode via the matching device 40 and the conductor 44. The radio-frequency power supply 38 is connected to the lower electrode via the matching device 42 and the conductor 44. The radio-frequency power supply 36 may be connected not to the lower electrode, but to the upper electrode to be described later via the matching device 40. The plasma processing apparatus 1 may not include any one of the set of the radio-frequency power supply 36 and the matching device 40 and the set of the radio-frequency power supply 38 and the matching device 42.

The radio-frequency power supply 36 outputs radio-frequency power RF1 for generating plasma. A basic frequency f_{B1} of the radio-frequency power RF1 is, for example, 100 MHz. The radio-frequency power supply 38 outputs radio-frequency power RF2 for drawing ions from the plasma into the substrate W. The frequency of the radio-frequency power RF2 is lower than the frequency of the radio-frequency power RF1. A basic frequency f_{B2} of the radio-frequency power RF2 is, for example, 13.56 MHz.

The matching device 40 has a circuit for matching the impedance on load side (e.g., lower electrode side) of the radio-frequency power supply 36 with the output impedance of the radio-frequency power supply 36. The matching device 42 has a circuit for matching the impedance on load side (lower electrode side) of the radio-frequency power supply 38 with the output impedance of the radio-frequency power supply 38. Each of the matching device 40 and the matching device 42 is an electronically controlled matching device. Details of each of the matching device 40 and the matching device 42 will be described later.

The matching device 40 and the conductor 44 constitute a part of a power feeding line 43. The radio-frequency power RF1 is supplied to the susceptor 16 via the power feeding line 43. The matching device 42 and the conductor 44 constitute a part of a power feeding line 45. The radio-frequency power RF2 is supplied to the susceptor 16 via the power feeding line 45.

The ceiling portion of the chamber 10 is constituted by an upper electrode 46. The upper electrode 46 is provided to close the opening at the upper end of the chamber body 12. The inner space of the chamber 10 includes a processing region PS. The processing region PS is a space between the upper electrode 46 and the susceptor 16. The plasma processing apparatus 1 generates plasma in the processing region PS by a radio-frequency electric field generated between the upper electrode 46 and the susceptor 16. The upper electrode 46 is grounded. When the radio-frequency power supply 36 is connected not to the lower electrode but to the upper electrode 46 via the matching device 40, the upper electrode 46 is not grounded, and the upper electrode 46 and the chamber body 12 are electrically isolated.

The upper electrode 46 has a ceiling plate 48 and a support 50. A plurality of gas injection holes 48a are formed in the ceiling plate 48. The ceiling plate 48 is made of a silicon-based material such as, for example, Si or SiC. The support 50 is a member that detachably supports the ceiling plate 48, and is made of aluminum. The support 50 is anodized on the surface thereof.

A gas buffer chamber 50b is formed inside the support 50. In addition, a plurality of gas holes 50a is formed in the support 50. Each of the plurality of gas holes 50a extends from the gas buffer chamber 50b and communicates with one of the plurality of gas injection holes 48a. A gas supply pipe 54 is connected to the gas buffer chamber 50b. The gas supply pipe 54 is connected with a gas source 56 via a flow rate controller 58 (e.g., a mass flow controller) and an opening/closing valve 60. The gas from the gas source 56 is supplied to the inner space of the chamber 10 via the flow rate controller 58, the opening/closing valve 60, the gas supply pipe 54, the gas buffer chamber 50b, and the plurality of gas injection holes 48a. The flow rate of the gas supplied from the gas source 56 to the inner space of the chamber 10 is adjusted by the flow rate controller 58.

An exhaust port 12e is provided in the bottom of the chamber body 12 below the space between the susceptor 16 and the side wall of the chamber body 12. An exhaust pipe 64 is connected to the exhaust port 12e. The exhaust pipe 64 is connected to an exhaust device 66. The exhaust device 66 has a pressure regulating valve and a vacuum pump such as, for example, a turbo molecular pump. The exhaust device 66 decompresses the inner space of the chamber 10 to a designated pressure.

The plasma processing apparatus 1 further has a main controller 70. The main controller 70 includes one or more microcomputers. The main controller 70 may include, for example, a processor, a storage device such as a memory, an input device such as a keyboard, a display device, and a signal input/output interface. The processor of the main controller 70 executes software (program) stored in the storage device and controls, based on recipe information, individual operations of the respective parts of the plasma processing apparatus 1, for example, the radio-frequency power supply 36, the radio-frequency power supply 38, the matching device 40, the matching device 42, the flow rate controller 58, the opening/closing valve 60, and the exhaust device 66, and the operation (sequence) of the entire apparatus of the plasma processing apparatus 1.

When the plasma processing is performed in the plasma processing apparatus 1, the gate valve 12g is first opened. Subsequently, the substrate W is loaded into the chamber 10 via the opening 12p and placed on the electrostatic chuck 18. Then, the gate valve 12g is closed. Next, processing gas is supplied from the gas source 56 to the inner space of the chamber 10, and the exhaust device 66 is activated to set the pressure in the inner space of the chamber 10 to a designated pressure. In addition, the radio-frequency power RF1 and/or the radio-frequency power RF2 are supplied to the susceptor 16. In addition, a DC voltage is applied from the DC power supply 24 to the electrode 20 of the electrostatic chuck 18, and the substrate W is held by the electrostatic chuck 18. Then, the processing gas is excited by a radio-frequency electric field formed between the susceptor 16 and the upper electrode 46. As a result, plasma is generated in the processing region PS.

The plasma processing apparatus 1 is configured to output modulated radio-frequency power from at least any one of the radio-frequency power supply 36 and the radio-frequency power supply 38. More specifically, by the control of the main controller 70 based on the recipe, the plasma processing apparatus 1 controls the radio-frequency power supply 36 and the radio-frequency power supply 38 in any one of first to third modes. In the first mode, the radio-frequency power supply 36 is controlled to output modulated radio-frequency power MRF1 as the radio-frequency power RF1, and the radio-frequency power supply 38 is controlled to output continuous radio-frequency power CRF2 as the radio-frequency power RF2. In the second mode, the radio-frequency power supply 36 is controlled to output continuous radio-frequency power CRF1 as the radio-frequency power RF1, and the radio-frequency power supply 38 is controlled to output modulated radio-frequency power MRF2 as the radio-frequency power RF2. In the third mode, the radio-frequency power supply 36 is controlled to output the modulated radio-frequency power MRF1 as the radio-frequency power RF1, and the radio-frequency power supply 38 is controlled to output the modulated radio-frequency power MRF2 as the radio-frequency power RF2. Further, in the following description, the modulated radio-frequency power MRF1 and the continuous radio-frequency power CRF1 are sometimes collectively called the radio-frequency power RF1, and the modulated radio-frequency power MRF2 and the continuous radio-frequency power CRF2 are sometimes collectively called the radio-frequency power RF2.

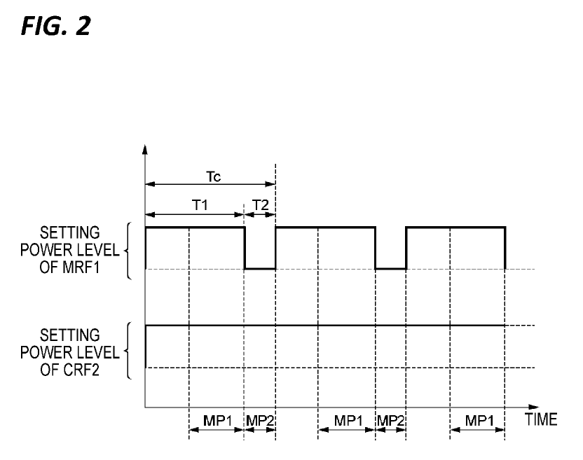

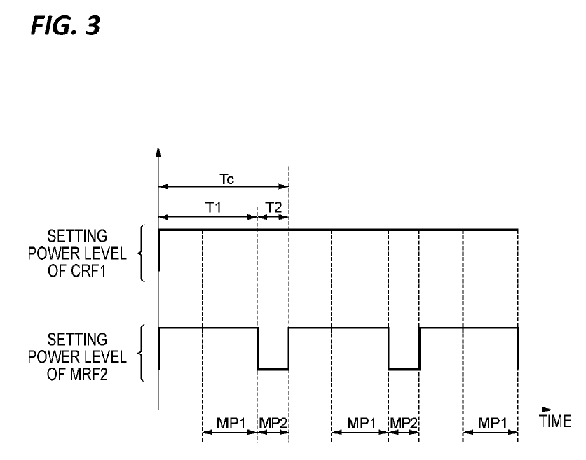

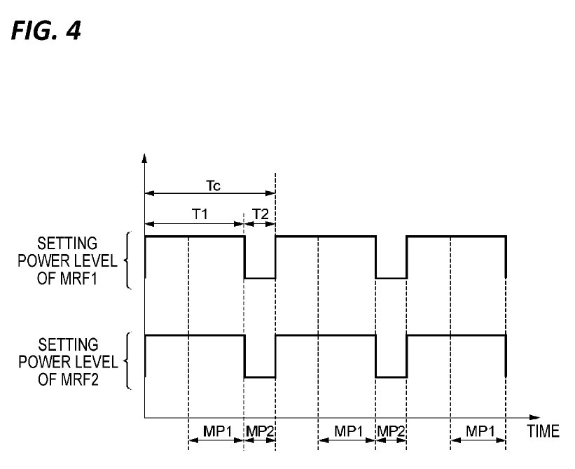

FIG. 2 is a view illustrating an exemplary timing chart of the first mode, FIG. 3 is a view illustrating an exemplary timing chart of the second mode, and FIG. 4 is a view illustrating an exemplary timing chart of the third mode. Hereinafter, the reference will be appropriately made to FIGS. 2 to 4.

As illustrated in FIGS. 2 and 4, the radio-frequency power supply 36 is configured to output the modulated radio-frequency power MRF1 in the first mode and the third mode. The modulated radio-frequency power MRF1 is modulated such that a power level thereof during a first period T1 is higher than a power level thereof during a second period T2. The second period T2 is a period that alternates with the first period. The first period T1 and the second period T2, which continues to the first period T1, constitute one cycle Tc. A ratio (duty ratio) of time length of the first period T1 occupied in the one cycle Tc may be controlled to any ratio. For example, the duty ratio may be controlled to a ratio within a range from 10% to 90%. In addition, a modulated frequency of the modulated radio-frequency power MRF1, that is, an inverse number of the one cycle Tc may be controlled to any modulated frequency. The modulated frequency of the modulated radio-frequency power MRF1 may be controlled to a frequency within a range, for example, from 1 kHz to 100 kHz.

In the first mode and the third mode, the power level of the modulated radio-frequency power MRF1 during the second period T2 may be 0 W. That is, in the first mode and the third mode, the modulated radio-frequency power MRF1 may not be supplied to the electrode (e.g., lower electrode) during the second period T2. Alternatively, in the first mode and the third mode, the power level of the modulated radio-frequency power MRF1 during the second period T2 may be higher than 0 W.

The radio-frequency power supply 36 is configured to output the continuous radio-frequency power CRF1 in the second mode. As illustrated in FIG. 3, the power level of the continuous radio-frequency power CRF1 is not modulated. An approximately constant power level continues in the continuous radio-frequency power CRF1.

As illustrated in FIGS. 3 and 4, the radio-frequency power supply 38 is configured to output the modulated radio-frequency power MRF2 in the second mode and the third mode. The modulated radio-frequency power MRF2 is modulated such that the power level thereof during the first period T1 is higher than the power level thereof during the second period T2. In the second mode and the third mode, the power level of the modulated radio-frequency power MRF2 during the second period T2 may be 0 W. That is, in the second mode and the third mode, the modulated radio-frequency power MRF2 may not be supplied to the electrode (lower electrode) during the second period T2. Alternatively, in the second mode and the third mode, the power level of the modulated radio-frequency power MRF2 during the second period T2 may be higher than 0 W.

The radio-frequency power supply 38 is configured to output the continuous radio-frequency power CRF2 in the first mode. As illustrated in FIG. 2, the power level of the continuous radio-frequency power CRF2 is not modulated. An approximately constant power level continues in the continuous radio-frequency power CRF2.

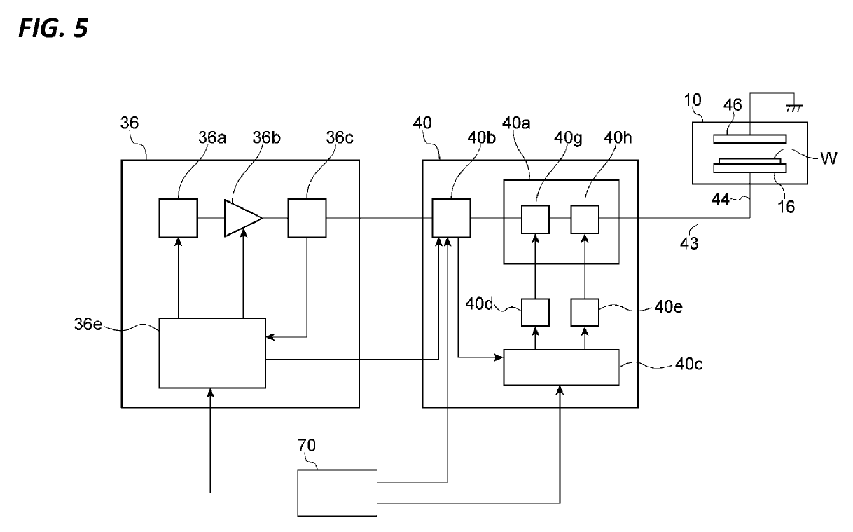

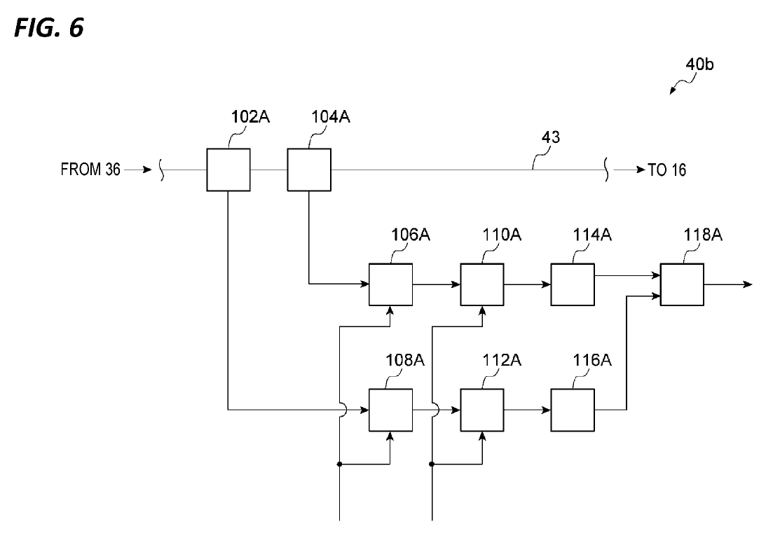

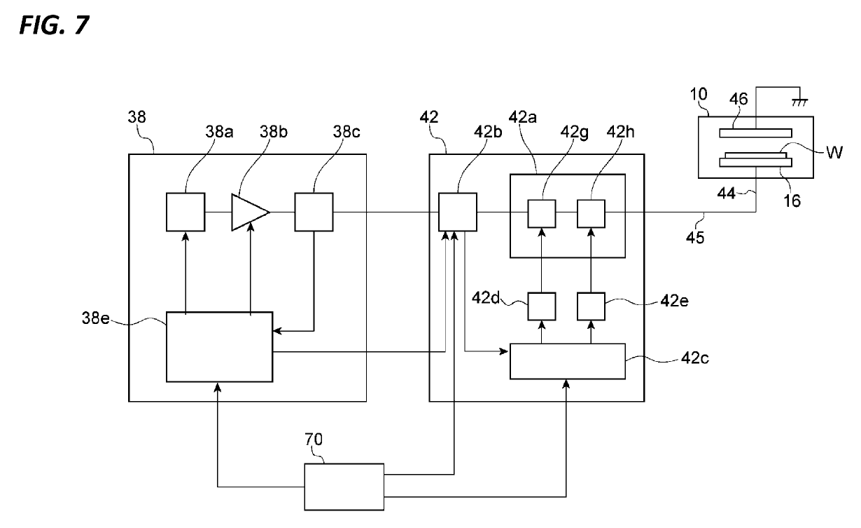

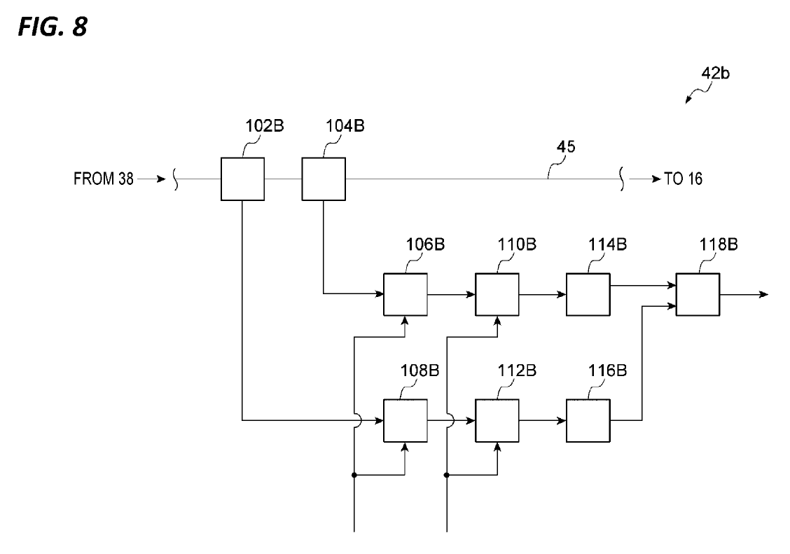

Hereinafter, the radio-frequency power supply 36, the matching device 40, the radio-frequency power supply 38, and the matching device 42 will be described in detail with reference to FIGS. 5 to 8. FIG. 5 is a view illustrating exemplary configurations of the radio-frequency power supply 36 and the matching device 40 of the plasma processing apparatus 1 illustrated in FIG. 1. FIG. 6 is a view illustrating an exemplary configuration of a sensor of the matching device 40 of the plasma processing apparatus 1 illustrated in FIG. 1. FIG. 7 is a view illustrating exemplary configurations of the radio-frequency power supply 38 and the matching device 42 of the plasma processing apparatus 1 illustrated in FIG. 1. FIG. 8 is a view illustrating an exemplary configuration of a sensor of the matching device 42 of the plasma processing apparatus 1 illustrated in FIG. 1.

As illustrated in FIG. 5, in the embodiment, the radio-frequency power supply 36 has an oscillator 36a, a power amplifier 36b, a power sensor 36c, and a power supply controller 36e. The power supply controller 36e is configured with a processor such as, for example, a CPU and controls the oscillator 36a, the power amplifier 36b, and the power sensor 36c by giving control signals to the oscillator 36a, the power amplifier 36b, and the power sensor 36c using a signal given from the main controller 70 and a signal given from the power sensor 36c.

The signal given from the main controller 70 to the power supply controller 36e includes a mode setting signal and a first frequency setting signal. The mode setting signal is a signal for designating a mode from the first mode, the second mode, and the third mode. The first frequency setting signal is a signal for designating a frequency of the radio-frequency power RF1. In a case where the radio-frequency power supply 36 operates in the first mode and the third mode, the signal given from the main controller 70 to the power supply controller 36e includes a first modulation setting signal and a first modulated power level setting signal. The first modulation setting signal is a signal for designating a modulated frequency and a duty ratio of the modulated radio-frequency power MRF1. The first modulated power level setting signal is a signal for designating the power level of the modulated radio-frequency power MRF1 during the first period T1 and the power level of the modulated radio-frequency power MRF1 during the second period T2. In a case where the radio-frequency power supply 36 operates in the second mode, the signal given from the main controller 70 to the power supply controller 36e includes a first power level setting signal for designating power of the continuous radio-frequency power CRF1.

The power supply controller 36e controls the oscillator 36a so as to output a radio-frequency signal having a frequency (e.g., the basic frequency f_{B1}) designated by the first frequency setting signal. The output of the oscillator 36a is connected to the input of the power amplifier 36b. The power amplifier 36b amplifies the radio-frequency signal output from the oscillator 36a so as to generate the radio-frequency power RF1, and outputs the radio-frequency power RF1. The power amplifier 36b is controlled by the power supply controller 36e.

In a case where the mode specified by the mode setting signal is any one of the first mode and the third mode, the power supply controller 36e controls the power amplifier 36b so as to generate the modulated radio-frequency power MRF1 from the radio-frequency signal in accordance with the first modulation setting signal and the first modulated power level setting signal from the main controller 70. Meanwhile, in a case where the mode specified by the mode setting signal is the second mode, the power supply controller 36e controls the power amplifier 36b so as to generate the continuous radio-frequency power CRF1 from the radio-frequency signal in accordance with the first power level setting signal from the main controller 70.

The power sensor 36c is provided at a rear stage of the power amplifier 36b. The power sensor 36c has a directional coupler, a traveling wave detector, and a reflected wave detector. The directional coupler gives a part of the traveling wave of the radio-frequency power RF1 to the traveling wave detector, and gives the reflected wave detector to the reflected wave. A first frequency specifying signal for specifying a setting frequency of the radio-frequency power RF1 is given from the power supply controller 36e to the power sensor 36c. The traveling wave detector generates a measured value P_{f11} of a power level of the traveling wave, that is, a measured value of a power level of a component which is one of all frequency components of the traveling wave and has a frequency equal to the setting frequency specified by the first frequency specifying signal. The measured value P_{f11} is given to the power supply controller 36e.

The first frequency specifying signal is also given from the power supply controller 36e to the reflected wave detector. The reflected wave detector generates a measured value Pᵣ₁₁ of a power level of a reflected wave, that is, a measured value of a power level of a component which is one of all frequency components of the reflected wave and has a frequency equal to the setting frequency specified by the first frequency specifying signal. The measured value Pᵣ₁₁ is given to the power supply controller 36e. In addition, the reflected wave detector generates a measured value of a total of the power levels of all of the frequency components of the reflected wave, that is, a measured value Pᵣ₁₂ of a power level of the reflected wave. The measured value Pᵣ₁₂ is given to the power supply controller 36e for protection of the power amplifier 36b.

In the first mode and the third mode, the power supply controller 36e controls the power amplifier 36b to adjust the power level of the modulated radio-frequency power MRF1 during the first period T1 such that a load power level P₁ during a monitoring period MP1 becomes a designated power level. In the second mode, the power supply controller 36e controls the power amplifier 36b to adjust the power level of the continuous radio-frequency power CRF1 such that the load power level P₁ during the monitoring period MP1 becomes a designated power level. The power level is designated by the main controller 70. The load power level P₁ is a difference between the power level of the traveling wave during the monitoring period MP1 and the power level of the reflected wave. The load power level P₁ is obtained as a difference between the measured value P_{f11} and the measured value Pᵣ₁₁ during the monitoring period MP1. The load power level P₁ may be obtained as a difference between an average value of the measured values P_{f11} and an average value of the measured values Pᵣ₁₁ during the monitoring period MP1. Alternatively, the load power level P₁ may be obtained as a difference between a moving average value of the measured values P_{f11} and a moving average value of the measured values Pᵣ₁₁ during a plurality of monitoring periods MP1. Further, in the second mode, the power supply controller 36e may control the power amplifier 36b to adjust the power level of the continuous radio-frequency power CRF1 such that an average value of the load power level P1 during the monitoring period MP1 and a load power level P1 during a monitoring period MP2 becomes a designated power level. The monitoring period MP1 and the monitoring period MP2 will be described below.

In the embodiment, the matching device 40 has a matching circuit 40a, a sensor 40b, a controller 40c, an actuator 40d, and an actuator 40e. The matching circuit 40a includes a variable reactance element 40g and a variable reactance element 40h. Each of the variable reactance element 40g and the variable reactance element 40h is, for example, a variable condenser. Further, the matching circuit 40a may further include, for example, an inductor.

The controller 40c operates under the control of the main controller 70. The controller 40c adjusts a load side impedance of the radio-frequency power supply 36 in accordance with a measured value of the load side impedance of the radio-frequency power supply 36 which is given from the sensor 40b. The controller 40c controls the actuator 40d and the actuator 40e to adjust reactance of the variable reactance element 40g and reactance of the variable reactance element 40h, thereby adjusting the load side impedance of the radio-frequency power supply 36. Each of the actuator 40d and the actuator 40e is, for example, a motor.

As illustrated in FIG. 6, the sensor 40b is configured to acquire the measured value of the load side impedance of the radio-frequency power supply 36. In the embodiment, the measured value of the load side impedance of the radio-frequency power supply 36 is acquired as a moving average value. In the embodiment, the sensor 40b has a current detector 102A, a voltage detector 104A, a filter 106A, a filter 108A, an average value calculator 110A, an average value calculator 112A, a moving average value calculator 114A, a moving average value calculator 116A, and an impedance calculator 118A.

The voltage detector 104A detects a voltage waveform of the radio-frequency power RF1 transmitted on the power feeding line 43, and outputs a voltage waveform analog signal that indicates the voltage waveform. The voltage waveform analog signal is input to the filter 106A. The filter 106A generates a voltage waveform digital signal by digitizing the input voltage waveform analog signal. Further, the filter 106A receives the first frequency specifying signal from the power supply controller 36e and extracts only a frequency component corresponding to a frequency specified by the first frequency specifying signal from the voltage waveform digital signal, thereby generating a filtered voltage waveform signal. Further, the filter 106A may be configured by, for example, a field programmable gate array (FPGA).

The filtered voltage waveform signal generated by the filter 106A is output to the average value calculator 110A. A monitoring period setting signal for designating the monitoring period MP1 is given from the main controller 70 to the average value calculator 110A. As illustrated in FIGS. 2 to 4, the monitoring period MP1 is a period within the first period T1. The monitoring period MP1 starts after a predetermined time length elapses from a start point of the first period T1. The average value calculator 110A obtains an average value V_{A11} of voltage during the monitoring period MP1 within the first period T1 from the filtered voltage waveform signal.

In the second mode, the monitoring period setting signal for designating the monitoring period MP2 may be given from the main controller 70 to the average value calculator 110A. The monitoring period MP2 may be a period that coincides with the second period T2. In this case, the average value calculator 110A may obtain an average value V_{A12} of voltage during the monitoring period MP2 from the filtered voltage waveform signal. Further, the average value calculator 110A may be configured by, for example, a field programmable gate array (FPGA).

The average value V_{A11} obtained by the average value calculator 110A is output to the moving average value calculator 114A. From a plurality of average values V_{A11} obtained in advance, the moving average value calculator 114A obtains a moving average value V_{MA11} of the average values V_{A11} which are obtained from the voltage of the radio-frequency power RF1 lately and during a predetermined number of monitoring periods of time MP1. The moving average value V_{MA11} is output to the impedance calculator 118A.

In the second mode, from a plurality of average values V_{A12} obtained in advance, the moving average value calculator 114A may further obtain a moving average value V_{MA12} of the average values V_{A12} which are obtained from the voltage of the radio-frequency power RF1 lately and during a predetermined number of monitoring periods of time MP2. In this case, the moving average value V_{MA12} is output to the impedance calculator 118A.

The current detector 102A detects a current waveform of the radio-frequency power RF1 transmitted on the power feeding line 43, and outputs a current waveform analog signal that indicates the current waveform. The current waveform analog signal is input to the filter 108A. The filter 108A generates a current waveform digital signal by digitizing the input current waveform analog signal. Further, the filter 108A receives the first frequency specifying signal from the power supply controller 36e and extracts only a frequency component corresponding to a frequency specified by the first frequency specifying signal from the current waveform digital signal, thereby generating a filtered current waveform signal. Further, the filter 108A may be configured by, for example, a field programmable gate array (FPGA).

The filtered current waveform signal generated by the filter 108A is output to the average value calculator 112A. The monitoring period setting signal for designating the monitoring period MP1 is given from the main controller 70 to the average value calculator 112A. The average value calculator 112A obtains an average value I_{A11} of current during the monitoring period MP1 within the first period T1 from the filtered current waveform signal.

In the second mode, the monitoring period setting signal for designating the monitoring period MP2 may be given from the main controller 70 to the average value calculator 112A. In this case, the average value calculator 112A may obtain an average value I_{A12} of current during the monitoring period MP2 from the filtered current waveform signal. Further, the average value calculator 112A may be configured by, for example, a field programmable gate array (FPGA).

The average value I_{A11} obtained by the average value calculator 112A is output to the moving average value calculator 116A. From a plurality of average values I_{A11} obtained in advance, the moving average value calculator 116A obtains a moving average value IMA11 of the average values I_{A11} which are obtained from the current of the radio-frequency power RF1 lately and during a predetermined number of monitoring periods of time MP1. The moving average value I_{MA11} is output to the impedance calculator 118A.

In the second mode, from a plurality of average values I_{A12} obtained in advance, the moving average value calculator 116A may further obtain a moving average value I_{MA12} of the average values I_{A12} which are obtained from the current of the radio-frequency power RF1 lately and during a predetermined number of monitoring periods of time MP2. In this case, the moving average value I_{MA12} is output to the impedance calculator 118A.

The impedance calculator 118A obtains a moving average value Z_{MA11} of the load side impedance of the radio-frequency power supply 36 from the moving average value I_{MA11} and the moving average value V_{MA11}. The moving average value Z_{MA11} obtained by the impedance calculator 118A is output to the controller 40c. The controller 40c adjusts the load side impedance of the radio-frequency power supply 36 by using the moving average value Z_{MA11}. Specifically, the controller 40c adjusts reactance of the variable reactance element 40g and reactance of the variable reactance element 40h by means of the actuator 40d and the actuator 40e such that the load side impedance of the radio-frequency power supply 36, which is specified by the moving average value Z_{MA11}, is set to an impedance that differs from an output impedance of the radio-frequency power supply 36.

In the embodiment, the controller 40c sets the load side impedance of the radio-frequency power supply 36 such that an absolute value |Γ₁| of a reflection coefficient Γ₁ of the radio-frequency power RF1 becomes a designated value. For example, the designated value is a value within a range from 0.3 to 0.5. Further, the reflection coefficient Γ₁ is defined by the following Equation (1).

Γ₁=(Z₁−Z₀₁)/(Z₁+Z₀₁) (1)

In Equation (1), Z₀₁ is a characteristic impedance of the power feeding line 43 and is generally 50Ω. In Equation (1), Z₁ is the load side impedance of the radio-frequency power supply 36. The moving average value Z_{MA11} may be used as Z₁ in Equation (1). The controller 40c retains a function or a table in which a relationship between the absolute value |Γ₁| of the reflection coefficient Γ₁ and the load side impedance of the radio-frequency power supply 36 is determined. The controller 40c may adjust the load side impedance of the radio-frequency power supply 36 by using the function or the table.

In the embodiment, in the second mode, in addition to the moving average value Z_{MA11}, the impedance calculator 118A may obtain the moving average value Z_{MA12} of the load side impedance of the radio-frequency power supply 36 from the moving average value I_{MA12} and the moving average value V_{MA12}. The moving average value Z_{MA12}, together with the moving average value Z_{MA11}, is output to the controller 40c. In this case, the controller 40c adjusts reactance of the variable reactance element 40g and reactance of the variable reactance element 40h by means of the actuator 40d and the actuator 40e such that the load side impedance of the radio-frequency power supply 36, which is specified by an average value of the moving average value Z_{MA11} and the moving average value Z_{MA12} coincides with or approximates to an output impedance (matching point) of the radio-frequency power supply 36.

As illustrated in FIG. 7, in the embodiment, the radio-frequency power supply 38 has an oscillator 38a, a power amplifier 38b, a power sensor 38c, and a power supply control unit 38e. The power supply control unit 38e is configured with a processor such as a CPU and controls the oscillator 38a, the power amplifier 38b, and the power sensor 38c by giving control signals to the oscillator 38a, the power amplifier 38b, and the power sensor 38c using a signal given from the main controller 70 and a signal given from the power sensor 38c.

The signal given from the main controller 70 to the power supply control unit 38e includes a mode setting signal and a second frequency setting signal. The mode setting signal is a signal for designating a mode from the first mode, the second mode, and the third mode. The second frequency setting signal is a signal for designating a frequency of the radio-frequency power RF2. In the case where the radio-frequency power supply 38 operates in the second mode and the third mode, the signal given from the main controller 70 to the power supply control unit 38e includes a second modulation setting signal and a second modulated power level setting signal. The second modulation setting signal is a signal for designating a modulated frequency and a duty ratio of the modulated radio-frequency power MRF2. The second modulated power level setting signal is a signal for designating the power level of the modulated radio-frequency power MRF2 during the first period T1 and the power level of the modulated radio-frequency power MRF2 during the second period T2. In a case where the radio-frequency power supply 38 operates in the first mode, the signal given from the main controller 70 to the power supply control unit 38e includes a second power level setting signal for designating power of the continuous radio-frequency power CRF2.

The power supply control unit 38e controls the oscillator 38a so as to output a radio-frequency signal having a frequency (e.g., the basic frequency f_{B2}) designated by the second frequency setting signal. The output of the oscillator 38a is connected to the input of the power amplifier 38b. The power amplifier 38b generates the radio-frequency power RF2 by amplifying the radio-frequency signal output from the oscillator 38a, and outputs the radio-frequency power RF2. The power amplifier 38b is controlled by the power supply control unit 38e.

In a case where the mode specified by the mode setting signal is any one of the second mode and the third mode, the power supply control unit 38e controls the power amplifier 38b so as to generate the modulated radio-frequency power MRF2 from the radio-frequency signal in accordance with the second modulation setting signal and the second modulated power level setting signal from the main controller 70. Meanwhile, in a case where the mode specified by the mode setting signal is the first mode, the power supply control unit 38e controls the power amplifier 38b so as to generate the continuous radio-frequency power CRF2 from the radio-frequency signal in accordance with the second power level setting signal from the main controller 70.

The power sensor 38c is provided at a rear stage of the power amplifier 38b. The power sensor 38c has a directional coupler, a traveling wave detector, and a reflected wave detector. The directional coupler gives a part of a traveling wave of the radio-frequency power RF2 to the traveling wave detector, and gives a reflected wave to the reflected wave detector. A second frequency specifying signal for specifying a setting frequency of the radio-frequency power RF2 is given from the power supply control unit 38e to the power sensor 38c. The traveling wave detector generates a measured value P_{f21} of a power level of the traveling wave, that is, a measured value of a power level of a component which is one of all frequency components of the traveling wave and has a frequency equal to the setting frequency specified by the second frequency specifying signal. The measured value P_{f21} is given to the power supply control unit 38e.

The second frequency specifying signal is also given from the power supply control unit 38e to the reflected wave detector. The reflected wave detector generates a measured value Pᵣ₂₁ of a power level of a reflected wave, that is, a measured value of a power level of a component which is one of all frequency components of the reflected wave and has a frequency equal to the setting frequency specified by the second frequency specifying signal. The measured value Pᵣ₂₁ is given to the power supply control unit 38e. In addition, the reflected wave detector generates a measured value of a total of the power levels of all of the frequency components of the reflected wave, that is, a measured value Pᵣ₂₂ of a power level of the reflected wave. The measured value Pᵣ₂₂ is given to the power supply control unit 38e for protection of the power amplifier 38b.

In the second mode and the third mode, the power supply control unit 38e controls the power amplifier 38b so as to adjust the power level of the modulated radio-frequency power MRF2 during the first period T1 such that a load power level P₂ during the monitoring period MP1 becomes a designated power level. In the first mode, the power supply control unit 38e controls the power amplifier 38b so as to adjust the power level of the continuous radio-frequency power CRF2 such that the load power level P₂ during the monitoring period MP1 becomes a designated power level. The power level is designated by the main controller 70. The load power level P₂ is a difference between the power level of the traveling wave during the monitoring period MP1 and the power level of the reflected wave. The load power level P₂ is obtained as a difference between the measured value Pᵣ₂₁ and the measured value Pᵣ₂₁ during the monitoring period MP1. The load power level P₂ may be obtained as a difference between an average value of the measured values Pᵣ₂₁ and an average value of the measured values Pᵣ₂₁ during the monitoring period MP1. Alternatively, the load power level P₂ may be obtained as a difference between a moving average value of the measured values Pᵣ₂₁ and a moving average value of the measured values Pᵣ₂₁ during a plurality of monitoring periods of time MP1. Further, in the first mode, the power supply control unit 38e may control the power amplifier 38b to adjust the power level of the continuous radio-frequency power CRF2 such that the load power level P2 during the monitoring period MP1 and an average value of the load power level P2 during the monitoring period MP2 become designated power levels.

In the embodiment, the matching device 42 has a matching circuit 42a, a sensor 42b, a controller 42c, an actuator 42d, and an actuator 42e. The matching circuit 42a includes a variable reactance element 42g and a variable reactance element 42h. Each of the variable reactance element 42g and the variable reactance element 42h is, for example, a variable condenser. Further, the matching circuit 42a may further include, for example, an inductor.

The controller 42c operates under the control of the main controller 70. The controller 42c adjusts a load side impedance of the radio-frequency power supply 38 in accordance with a measured value of the load side impedance of the radio-frequency power supply 38 which is given from the sensor 42b. The controller 42c adjusts reactance of the variable reactance element 42g and reactance of the variable reactance element 42h by controlling the actuator 42d and the actuator 42e, thereby adjusting the load side impedance of the radio-frequency power supply 38. Each of the actuator 42d and the actuator 42e is, for example, a motor.

As illustrated in FIG. 8, the sensor 42b is configured to acquire the measured value of the load side impedance of the radio-frequency power supply 38. In the embodiment, the measured value of the load side impedance of the radio-frequency power supply 38 is acquired as a moving average value. In the embodiment, the sensor 42b has a current detector 102B, a voltage detector 104B, a filter 106B, a filter 108B, an average value calculator 110B, an average value calculator 112B, a moving average value calculator 114B, a moving average value calculator 116B, and an impedance calculator 118B.

The voltage detector 104B detects a voltage waveform of the radio-frequency power RF2 transmitted on the power feeding line 45, and outputs a voltage waveform analog signal that indicates the voltage waveform. The voltage waveform analog signal is input to the filter 106B. The filter 106B generates a voltage waveform digital signal by digitizing the input voltage waveform analog signal. Further, the filter 106B receives the second frequency specifying signal from the power supply control unit 38e and extracts only a frequency component corresponding to a frequency specified by the second frequency specifying signal from the voltage waveform digital signal, thereby generating the filtered voltage waveform signal. Further, the filter 106B may be configured by, for example, a field programmable gate array (FPGA).

The filtered voltage waveform signal generated by the filter 106B is output to the average value calculator 110B. The monitoring period setting signal for designating the monitoring period MP1 is given from the main controller 70 to the average value calculator 110B. The average value calculator 110B obtains an average value V_{A21} of voltage during the monitoring period MP1 within the first period T1 from the filtered voltage waveform signal.

In the first mode, the monitoring period setting signal for designating the monitoring period MP2 may be given from the main controller 70 to the average value calculator 110B. In this case, the average value calculator 110B may obtain an average value V_{A22} of voltage during the monitoring period MP2 from the filtered voltage waveform signal. Further, the average value calculator 110B may be configured by, for example, a field programmable gate array (FPGA).

The average value V_{A21} obtained by the average value calculator 110B is output to the moving average value calculator 114B. From a plurality of average values V_{A21} obtained in advance, the moving average value calculator 114B obtains a moving average value V_{MA21} of the average values V_{A21} which are obtained from the voltage of the radio-frequency power RF2 lately and during a predetermined number of monitoring periods of time MP1. The moving average value V_{MA21} is output to the impedance calculator 118B.

In the first mode, from a plurality of average values V_{A22} obtained in advance, the moving average value calculator 114B may further obtain a moving average value V_{MA22} of the average values V_{A22} which are obtained from the voltage of the radio-frequency power RF2 lately and during a predetermined number of monitoring periods of time MP2. In this case, the moving average value V_{MA22} is output to the impedance calculator 118B.

The current detector 102B detects a current waveform of the radio-frequency power RF2 transmitted on the feeding supply line 45, and outputs a current waveform analog signal that indicates the current waveform. The current waveform analog signal is input to the filter 108B. The filter 108B generates a current waveform digital signal by digitizing the input current waveform analog signal. Further, the filter 108B receives the second frequency specifying signal from the power supply control unit 38e and extracts only a frequency component corresponding to a frequency specified by the second frequency specifying signal from the current waveform digital signal, thereby generating the filtered current waveform signal. Further, the filter 108B may be configured by, for example, a field programmable gate array (FPGA).

The filtered current waveform signal generated by the filter 108B is output to the average value calculator 112B. The monitoring period setting signal for designating the monitoring period MP1 is given from the main controller 70 to the average value calculator 112B. The average value calculator 112B obtains an average value I_{A21} of current during the monitoring period MP1 within the first period T1 from the filtered current waveform signal.

In the first mode, the monitoring period setting signal for designating the monitoring period MP2 may be given from the main controller 70 to the average value calculator 112B. In this case, the average value calculator 112B may obtain an average value I_{A22} of current during the monitoring period MP2 from the filtered current waveform signal. Further, the average value calculator 112B may be configured by, for example, a field programmable gate array (FPGA).

The average value I_{A21} obtained by the average value calculator 112B is output to the moving average value calculator 116B. From a plurality of average values I_{A21} obtained in advance, the moving average value calculator 116B obtains a moving average value I_{MA21} of the average values I_{A21} which are obtained from the current of the radio-frequency power RF1 lately and during a predetermined number of monitoring periods of time MP1. The moving average value I_{MA21} is output to the impedance calculator 118B.

In the first mode, from a plurality of average values I_{A22} obtained in advance, the moving average value calculator 116B may further obtain a moving average value I_{MA22} of the average values I_{A22} which are obtained from the current of the radio-frequency power RF2 lately and during a predetermined number of monitoring periods of time MP2. In this case, the moving average value I_{MA22} is output to the impedance calculator 118B.

The impedance calculator 118B obtains a moving average value Z_{MA21} of the load side impedance of the radio-frequency power supply 38 from the moving average value I_{MA21} and the moving average value V_{MA21}. The moving average value Z_{MA21} obtained by the impedance calculator 118B is output to the controller 42c. The controller 42c adjusts the load side impedance of the radio-frequency power supply 38 by using the moving average value Z_{MA21}. Specifically, the controller 40c adjusts reactance of the variable reactance element 42g and reactance of the variable reactance element 42h by means of the actuator 42d and the actuator 42e such that the load side impedance of the radio-frequency power supply 38, which is specified by the moving average value Z_{MA21}, is set to an impedance that differs from an output impedance of the radio-frequency power supply 38.

In the embodiment, the controller 42c sets the load side impedance of the radio-frequency power supply 38 such that an absolute value |Γ₂| of a reflection coefficient Γ₂ of the radio-frequency power RF2 becomes a designated value. For example, the designated value is a value within a range from 0.3 to 0.5. Further, the reflection coefficient Γ₂ is defined by the following Equation (2).

Γ₂=(Z₂−Z₀₂)/(Z₂+Z₀₂) (2)

In Equation (2), Z₀₂ is a characteristic impedance of the power feeding line 45 and is generally 50Ω. In Equation 2, Z₂ is the load side impedance of the radio-frequency power supply 38. The moving average value Z_{MA21} may be used as Z₂ in Equation (2). The controller 42c retains a function or a table in which a relationship between the absolute value |Γ₂| of the reflection coefficient Γ₂ and the load side impedance of the radio-frequency power supply 38 is determined. The controller 42c may adjust the load side impedance of the radio-frequency power supply 38 by using the function or the table.

In the embodiment, in the first mode, in addition to the moving average value Z_{MA21}, the impedance calculator 118B may obtain the moving average value Z_{MA22} of the load side impedance of the radio-frequency power supply 38 from the moving average value I_{MA22} and the moving average value V_{MA22}. The moving average value Z_{MA22}, together with the moving average value Z_{MA21}, is output to the controller 42c. In this case, the controller 42c adjusts reactance of the variable reactance element 42g and reactance of the variable reactance element 42h by means of the actuator 42d and the actuator 42e such that the load side impedance of the radio-frequency power supply 38, which is specified by an average value of the moving average value Z_{MA21} and the moving average value Z_{MA22} coincides with or approximates to an output impedance (matching point) of the radio-frequency power supply 38.

In the case where the modulated radio-frequency power is used in the plasma processing apparatus 1, the load side impedance during the monitoring period MP1 is set to an impedance that differs from the output impedance (matching point) of the radio-frequency power supply. As a result, reflection of the modulated radio-frequency power is reduced. In the case where the load side impedance differs from the matching point, the power level of the radio-frequency power is adjusted such that the load power level becomes a designated power level even though the reflection cannot be completely eliminated, and as a result, the modulated radio-frequency power having the designated power level is coupled to plasma.

While various embodiments have been described above, various modified modes may be configured without being limited to the aforementioned embodiments. For example, the plasma processing apparatus 1 is a capacitively coupled plasma processing apparatus, but the spirit of the present disclosure may be applied to any plasma processing apparatus which is configured to supply modulated radio-frequency power from a radio-frequency power supply to an electrode. An inductively coupled plasma processing apparatus is considered as an example of the plasma processing apparatus.

In addition, the above description shows that the plasma processing apparatus 1 uses both of the radio-frequency power RF1 and the radio-frequency power RF2 in order to perform plasma processing, but only any one of the radio-frequency power RF1 and the radio-frequency power RF2 may be used to perform plasma processing.

Hereinafter, an experiment, which has been performed to evaluate the plasma processing apparatus 1, will be described. Further, the present disclosure is not limited by the experiment to be described below.

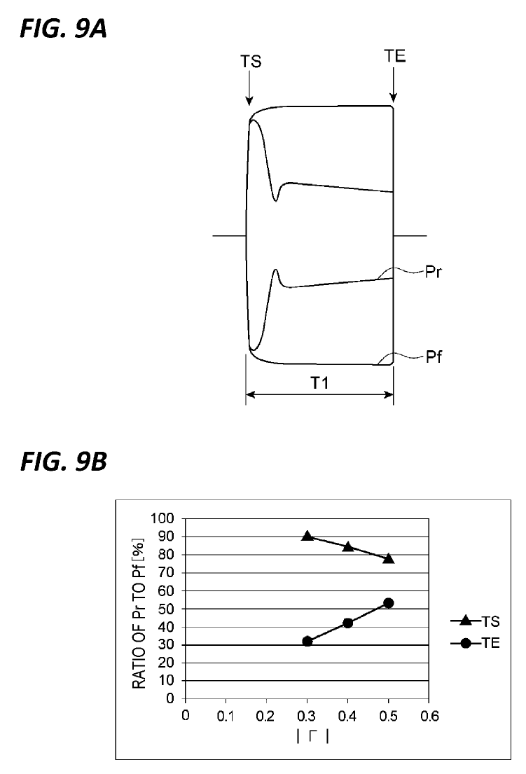

In the experiment, plasma was generated in the chamber 10 by using the plasma processing apparatus 1 and supplying the continuous radio-frequency power CRF1 and the modulated radio-frequency power MRF2 to the susceptor 16. Further, at each of a start point TS and an end point TE of the first period T1, the power level Pf of the traveling wave and the power level Pr of the reflected wave of the modulated radio-frequency power MRF2 were measured (see FIG. 9A). In the experiment, the absolute value Ill of the reflection coefficient F of the modulated radio-frequency power MRF2 was set to various values. Other conditions of the experiment are as follows.

<Condition of Experiment>

Continuous radio-frequency power CRF1: 60 MHz, 1,200 W

Frequency of modulated radio-frequency power MRF2: 40.68 MHz

Modulated frequency of modulated radio-frequency power MRF2: 10 kHz

Duty ratio of modulated radio-frequency power MRF2: 50%

Setting power level of modulated radio-frequency power MRF2 during first period T1: 1,000 W

Setting power level of modulated radio-frequency power MRF2 during second period T2: 0 w

Pressure in chamber 10: 2.67 Pa

Gas supplied to inner space of chamber 10: CF4 gas (50 sccm), Ar gas (600 sccm)

FIG. 9B illustrates a result of the experiment. In the graph in FIG. 9B, the horizontal axis indicates the absolute value |Γ| of the reflection coefficient Γ. In the graph in FIG. 9B, the vertical axis indicates a ratio (hereinafter, simply referred to as a “ratio”) of the power level Pr of the reflected wave to the power level Pf of the traveling wave at the start point TS of the first period T1 or the end point TE of the first period T1. According to the result of the experiment, in a case where the absolute values |Γ| of the reflection coefficient Γ were set to 0, 0.1, and 0.2, the power level Pr of the reflected wave was not stable at the end point TE, and in some instances, the ratio was about 100%. Meanwhile, it was ascertained that in a case where the absolute values |Γ| of the reflection coefficient Γ were set to values equal to or larger than 0.3 and equal to or smaller than 0.5, the ratio was significantly decreased, and the reflected wave was reduced. Further, in a case where the absolute value |Γ| of the reflection coefficient Γ is larger than 0.5, it is necessary to use a radio-frequency power supply having a significantly high rated output in order to ensure the load power level. Therefore, since the absolute value |Γ| of the reflection coefficient Γ is set to a value equal to or larger than 0.3 and equal to or smaller than 0.5, the reflected wave of the radio-frequency power is reduced, and it is possible to ensure a required load power level by using a radio-frequency power supply having a comparatively low rated output.

As described above, it is possible to reduce the reflection of the modulated radio-frequency power.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a chamber;
a radio-frequency power supply;
an electrode electrically connected to the radio-frequency power supply in order to generate plasma in the chamber; and
a matching device connected between the radio-frequency power supply and the electrode,
wherein the radio-frequency power supply outputs radio-frequency power generated such that a power level during a first period is higher than a power level during a second period alternating with the first period,
the matching device sets a load side impedance of the radio-frequency power supply during a monitoring period within the first period to an impedance that differs from an output impedance of the radio-frequency power supply, the monitoring period is a period starting after a predetermined time length elapses from a start point of the first period, and
the radio-frequency power supply adjusts the power level of the radio-frequency power such that a load power level, which is a difference between a power level of a traveling wave and a power level of a reflected wave, becomes a designated power level.

2. The plasma processing apparatus of claim 1, wherein the matching device sets the load side impedance such that an absolute value of a reflection coefficient of the radio-frequency power becomes a designated value.

3. The plasma processing apparatus of claim 2, wherein the designated value ranges from 0.3 to 0.5.
